(19) United States
(12) Patent Application Publication
(10) Pub. No.: US 2012/0119217 A1
(43) Pub. Date: May 17, 2012

(54) NONPLANAR DISPLAY DEVICE AND METHOD OF MANUFACTURING THE SAME

(75) Inventor: Yasushi KAWATA, Saitama-ken (JP)

(73) Assignee: Toshiba Mobile Display Co., Ltd., Fukaya-shi (JP)

(21) Appl. No.: 13/296,520

(22) Filed: Nov. 15, 2011

(30) Foreign Application Priority Data
Nov. 17, 2010 (JP) 2010-256987

(51) Int. Cl. H01L 29/786; H01J 9/00

(52) U.S. Cl. 257/72; 445/24; 257/E29.273

(57) ABSTRACT

In one embodiment, a nonplanar display devise includes an array substrate and a counter substrate formed of non-glass material. The array substrate includes a polishing stopper layer formed on a glass substrate. A ground layer is formed on a polishing layer. A switching element is arranged on the ground layer, and a pixel electrode is connected to the switching element. The nonplanar display device is manufactures as follows. First, the glass substrate is removed from the display cell. Then, the polishing stopper layer of the array substrate is removed. Finally, the nonplanar display device is manufactured by attaching an exposed ground layer of the array substrate and an insulating layer formed of the non-glass material in the display cell.

### CROSS-REFERENCE TO RELATED APPLICATION

This application is based upon and claims the benefit of priority from Japanese Patent Application No. 2010-256987, filed Nov. 17, 2010, the entire contents of which are incorporated herein by reference.

### FIELD

Embodiments described herein relate generally to a nonplanar display device and a method of manufacturing the same.

### BACKGROUND

The flat display device represented by the liquid crystal display device is used in various fields as displays for an OA equipment such as a personal computer, an information terminal, a clock, and a television set, taking advantage of the features, such as a light weight, a thin shape, and low power consumption. In recent years, the flat display device is also used as a display device for a personal digital assistant device such as a cellular phone and PDA (personal digital assistant). The demand for thinner and light characteristics is increasing in the flat display device used in such various fields from viewpoints of design, portability, etc., not only performance.

For example, the liquid crystal display device, which can achieve much more slimming-down structure, is proposed. Generally, a quartz substrate or a glass substrate are used from viewpoints of heat resistance etc., as the substrate material which forms a thin film transistor. A thin plate and a weight saving are attained by polishing the substrate mechanically, chemically, etc. Furthermore, new trial is also examined, that is, as another method of achieving the weight saving, the glass substrates are once removed, and a TFT thin film containing a thin film transistor, etc., is transcribed to other resin substrate with light weight, etc.

However, in order to transcribe the TFT thin film, we have concerns about the cost rising due to increase of indirect components, such as a support substrate, a medicine shield film, and temporary attaching adhesives, for preventing the TFT thin film from curling by remaining stress, for improving the chemical resistance and handling nature in a manufacturing process. Furthermore, a large-scale change of the conventional manufacturing process, etc., is needed because a new equipment is necessary for assembling various display panels, such as a liquid crystal display panel using the film substrate.

### BRIEF DESCRIPTION OF THE DRAWINGS

The accompanying drawings, which are incorporated in and constitute a portion of the specification, illustrate embodiments of the invention, and together with the general description given above and the detailed description of the embodiments given below, serve to explain the principles of the invention.

FIG. 1 is a figure schematically showing a structure of a nonplanar display device in this embodiment.

FIG. 2 is a cross-sectional view schematically showing one example of a first structure of a liquid crystal display panel shown in FIG. 1.

FIG. 3 is a figure for explaining a manufacturing method of the liquid crystal display panel of the example of the first structure shown in FIG. 2, and is a cross-sectional view for explaining the process of forming a display cell.

FIG. 4 is a figure for explaining the manufacturing method of the liquid crystal display panel of the example of the first structure shown in FIG. 2, and is a plan view for explaining the process of forming a display cell.

FIG. 5 is a figure for explaining the manufacturing method of the liquid crystal display panel of the example of the first structure shown in FIG. 2, and is a cross-sectional view for explaining the process of removing a glass substrate of an array substrate.

FIG. 6 is a figure for explaining the manufacturing method of the liquid crystal display panel of the example of the first structure shown in FIG. 2, and is a cross-sectional view for explaining the process of removing a polishing stopper layer of the array substrate.

FIG. 7 is a figure for explaining the manufacturing method of the liquid crystal display panel of the example of the first structure shown in FIG. 2, and is a cross-sectional view for explaining the process of attaching a first insulating substrate.

FIG. 8 is a figure for explaining the manufacturing method of the liquid crystal display panel of the example of the first structure shown in FIG. 2, and is a cross-sectional view for explaining other process of attaching the first insulating substrate.

FIG. 9 is a cross-sectional view schematically showing an example of the second structure of the liquid crystal display panel shown in FIG. 1.

FIG. 10 is a figure for explaining the manufacturing method of the liquid crystal display panel of the example of the second structure shown in FIG. 9, and is a cross-sectional view for explaining the process of forming a display cell.

FIG. 11 is a figure for explaining the manufacturing method of the liquid crystal display panel of the example of the second structure shown in FIG. 9, and is a cross-sectional view for explaining the process of making the glass substrate of the array substrate thinner.

FIG. 12 is a figure for explaining the manufacturing method of the liquid crystal display panel of the example of the second structure shown in FIG. 9, and is a cross-sectional view for explaining the process of attaching the first insulating substrate.

FIG. 13 is a figure for explaining the manufacturing method of the liquid crystal display panel of the example of the second structure shown in FIG. 9, and is a cross-sectional view for explaining other process of attaching the first insulating substrate.

### DETAILED DESCRIPTION

A nonplanar display device and a method of manufacturing the same according to an exemplary embodiment of the present invention will now be described with reference to the accompanying drawings wherein the same or like reference numerals designate the same or corresponding portions throughout the several views.

According to one embodiment, a nonplanar display device includes: an array substrate having a glass substrate, a polishing stopper layer formed on the glass substrate, a ground layer formed on the polishing layer, a switching element arranged on the ground layer, and a pixel electrode connected to the switching element; and a counter substrate formed of non-glass material. The manufacturing method of the nonplanar display device comprises the steps: forming a display cell by attaching the array substrate and the counter substrate; removing the glass substrate from the display cell; removing the polishing stopper layer of the array substrate; and manufacturing the nonplanar display device by attaching the exposed ground layer of the array substrate and an insulating layer formed of the non-glass material in the display cell.

According to other embodiment, a nonplanar display device includes an array substrate and a counter substrate formed of non-glass material. The array substrate includes a glass substrate, a switching element arranged on the glass substrate, and a pixel electrode connected to the switching element. The method of manufacturing the nonplanar display device includes the steps: forming a display cell by attaching the array substrate and the counter substrate; making the glass substrate of the array substrate thinner; and manufacturing the nonplanar display device by attaching the glass substrate of the array substrate and an insulating layer formed of the non-glass material.

According to other embodiment, a nonplanar display device includes: an array substrate having an insulating substrate formed of non-glass material, a ground layer attached to the insulating layer, a switching element arranged on the ground layer, and a pixel electrode connected to the switching element, and a counter substrate formed of non-glass material and attached to the array substrate.

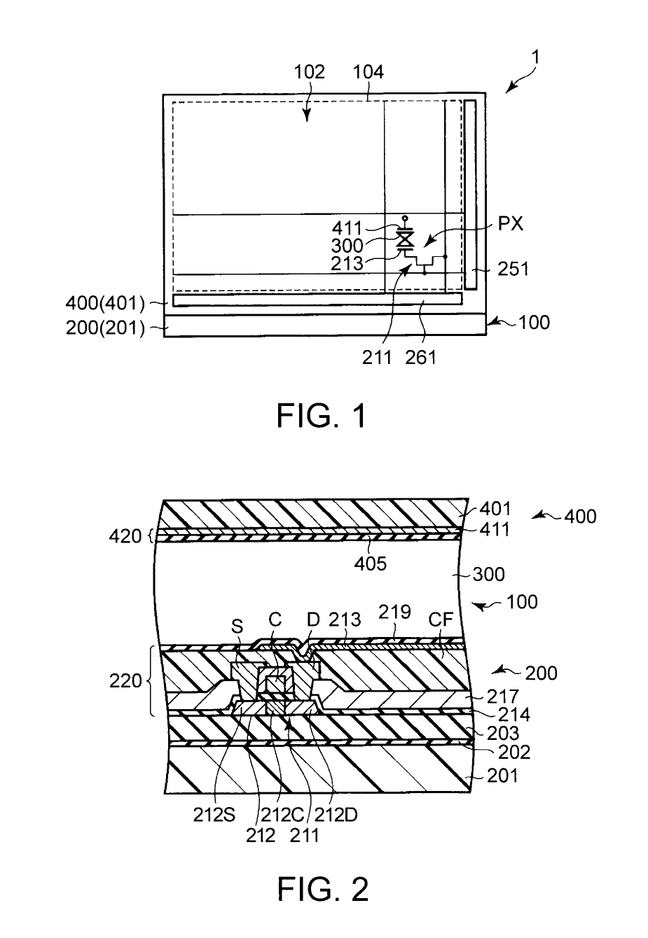

FIG. 1 is a figure schematically showing the structure of the nonplanar display device in this embodiment. In addition, although a liquid crystal display device is explained as an example of the nonplanar display device, a self-luminescence type display device, such as an organic electroluminescence (EL) display device equipped with a self-luminous emitting element, may be used.

The liquid crystal display device 1 is equipped with a liquid crystal display panel 100. That is, the liquid crystal display panel 100 includes an array substrate 200, a counter substrate 400, and a liquid crystal layer 300 held between the array substrate 200 and the counter substrate 400. The liquid crystal display panel 100 has an effective display region 102 which displays an image.

The effective display region 102 is formed in the inside surrounded by a seal material 104 which attaches the array substrate 200 and the counter substrate 400 with a predetermined gap therebetween. The effective display region 102 is equipped with a plurality of display pixels PX arranged in the shape of a matrix. In addition, in the example shown here, the seal material 104 is formed in the shape of a closed loop, and an injecting mouth for injecting liquid crystal materials is not formed.

The array substrate 200 is formed using a first insulating substrate 201 which has a thickness of 0.2 mm or less (a thickness of 0.1 mm, in this embodiment). The array substrate 200 includes a plurality of signal lines X and scanning lines Y formed in the shape of a matrix on the first principal surface (inside), and a plurality of switching elements 211 constituted by a thin film transistor, etc., arranged near the intersection of the signal line X and the scanning line Y, and a pixel electrode 213 connected to the switching element 211.

The counter substrate 400 is formed using a second insulating substrate 401 which has a thickness of 0.2 mm or less (a thickness of 0.1 mm, in this embodiment). The counter substrate 400 is equipped with a counter electrode 411 facing the pixel electrode 213 and arranged on the first principal surface (inside) in the effective display region 102.

The driving circuit unit 110 located around the effective display region 102 is equipped with a scanning line driving circuit unit 251 connected to the plurality of scanning lines Y, and a signal line driving circuit unit 261 connected to the plurality of signal lines X. The scanning line driving circuit unit 251 supplies a driving signal (scanning signal) to each scanning line Y. Moreover, the signal line driving circuit unit 261 supplies a driving signal (pixel signal) to each signal line X.

FIG. 2 is a cross-sectional view schematically showing one example of the first structure of the liquid crystal display panel 100 shown in FIG. 1.

The first insulating substrate 201 which constitutes the array substrate 200 is formed of a transmissive substrate made of the non-glass material. The first insulating substrate 201 is attached on a ground insulating layer 203 with adhesives 202. The adhesives 202 are formed of ultraviolet curing type resin, etc. The ground insulating layer 203 is formed with silicon oxide (SiO), for example. The switching element 211, the pixel electrode 213, etc. are formed on the ground insulating layer 203.

The switching element 211 includes a semiconductor layer 212. The semiconductor layer 212 is formed of polycrystalline silicon, amorphous silicon, etc. Although the switching element 211 formed of a thin film transistor of the top-gate type equipped with the polycrystalline silicon semiconductor layer is explained here, the thin film transistor of a bottom gate-type may be used, not only the top-gate type.

The semiconductor layer 212 includes a channel region 212C, and a source region 212S and a drain region 212D arranged so as to sandwich the channel region 212C from both sides. The semiconductor layer 212 is covered with a gate insulating film 214. Moreover, the gate insulating film 214 is arranged also on the ground insulating layer 203.

The gate electrode G of the switching element 211 is formed on the gate insulating film 214, and is arranged above the channel region 212C. The gate electrode G is electrically connected to the scanning line Y which is not illustrated. The gate electrode G is covered with an interlayer insulating film 217. Moreover, the interlayer insulating film 217 is arranged on the gate insulating film 214.

The source electrode S and the drain electrode D of the switching element 211 are formed on the interlayer insulating film 217. The source electrode S is electrically connected to the source region 212S. The source electrode S is electrically connected to the signal line X which is not illustrated. The drain electrode D is electrically connected to the drain region 212D. The switching element 211 is covered with a color filter layer CF. Moreover, the color filter layer CF is arranged also on the interlayer insulating film 217.

The pixel electrode 213 is formed on the color filter layer CF. The pixel electrode 213 is formed of ITO (Indium Tin Oxide), IZO (Indium Zinc Oxide), etc. The pixel electrode 213 is electrically connected to the drain electrode D of the switching element 211. An alignment film 219 is arranged on the whole surface of the effective display region 102 so that all the pixel electrodes 213 are covered.

In addition, the switching element 211, the gate insulating film 214, the interlayer insulating film 217, the color filter layer CF, the pixel electrode 213 and the alignment film 219 formed on the liquid crystal layer 300 side rather than the ground insulating layer 203 are collectively called “the first pixel formation part 220” in the array substrate 200 in this embodiment.

The second insulating substrate 401 constituting the counter substrate 400 is formed of a transmissive substrate, and is practically formed of the non-glass material like the first insulating substrate 201. A counter electrode 411 is formed opposing the array substrate 200 in the second insulating substrate 401. The counter electrode 411 is formed of ITO, IZO, etc. An alignment film 405 is arranged all over the effective display region 102 so that the whole counter electrode 411 may be covered.

In addition, the counter electrode 411 and the alignment film 405 formed on the liquid crystal layer 300 side rather than the second insulating substrate 401 are collectively called “the second pixel formation part 420” in the counter substrate 400 in this embodiment.

A pillar-shaped spacer for forming a predetermined cell gap (which is not illustrated) is arranged between the array substrate 200 and the counter substrate 400. The liquid crystal layer 300 is formed of the liquid crystal material enclosed in the cell gap between the array substrate 200 and the counter substrate 400. The liquid crystal layer 300 is formed by one drop filling method to be mentioned later.

In addition, although not illustrated, optical elements including a polarizing plate, etc., are respectively attached to a second principal surface (external surface) of the first insulating substrate 201 constituting the array substrate 200 and a second principal surface (external surface) of a second insulating substrate 401 constituting the counter substrate 400.

As the non-glass material described here, a high heat resistance substrate formed of single resin film such as resin materials, aramid resin, polyimide resin, epoxy resin, and various hybrid resin substrate formed of above mentioned resin materials and glass fiber, is applicable. As the product name, PES, PEN, and NEOPRIM are famous. However, various materials may be used if the materials have suitable transmissivity, heat-resistance and chemical resistance as a substrate constituting the display cell, such as the liquid crystal display panel.

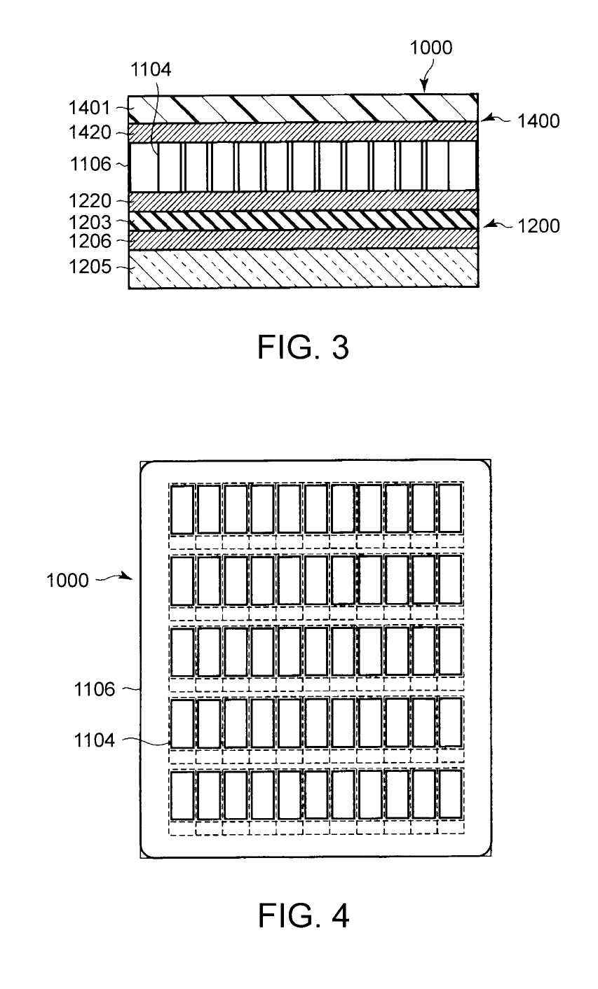

Next, a manufacturing method of the liquid crystal display panel 100 of one example of the first structure shown in FIG. 2 is explained referring to FIG. 3 and FIG. 4. Here, the manufacturing method of the multiple pattern cells is explained for forming a plurality of liquid crystal display panels 100 from a large-sized display cell 1000 as an example.

Here, after forming the polishing stopper layer 1206 on a glass substrate 1205 and a ground insulating layer 1203 on a polishing stopper layer 1206, a first pixel formation part 1220 is formed on the ground insulating layer 1203. Thereby, a large-sized array substrate 1200 is completed. It is preferable to use a thin film formed of the material which has fluorinated acid resistance characteristics, such as amorphous silicon (a-Si), as the polishing stopper layer 1206.

On the other hand, a second pixel formation part 1420 is formed on a second insulating substrate 1401 formed of the non-glass material. Thereby, a large-sized counter substrate 1400 is completed.

Then, after applying a seal material 1104 and a temporary seal material 1106 so that all the effective display regions are surrounded along an outer edge of the array substrate 1200 and the counter substrate 1400, the liquid crystal material is dropped at each effective display region, and then the array substrate 1200 and the counter substrate 1400 are attached together with a predetermined cell gap. Thereby, a display cell 1000 is manufactured enclosing the liquid crystal material in each effective display region.

As the seal material 1104 and the temporary seal material 1106, various adhesives, such as an optical (for example, ultraviolet rays) curing type can be used. The array substrate 1200 and the counter substrate 1400 are attached by irradiating with the light of a predetermined wavelength by curing the adhesives.

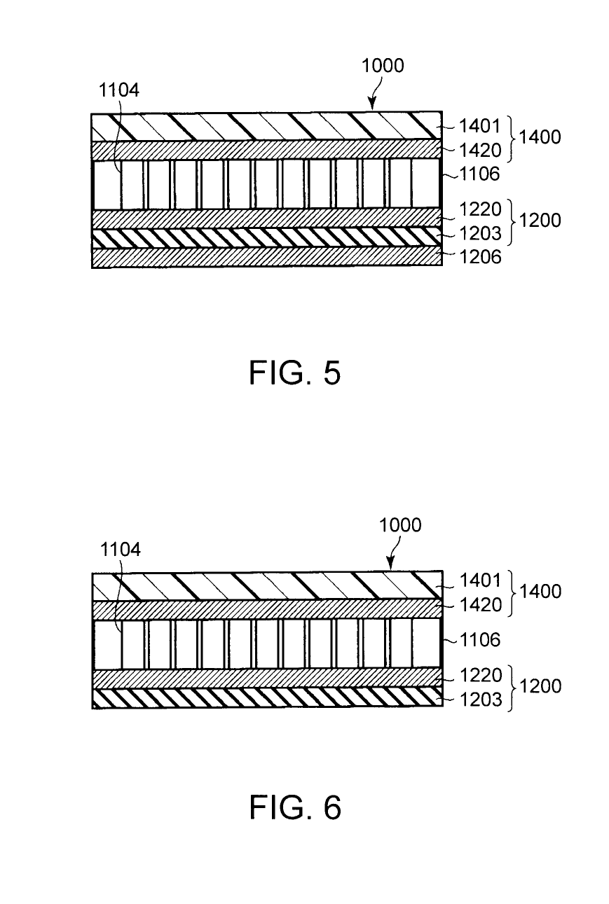

Then, as shown in FIG. 5, the glass substrate 1205 of the array substrate 1200 is removed from the display cell 1000. Here, the glass substrate 1205 of the array substrate 1200 is polished by performing chemical polish processing for the unified array substrate 1200 and the counter substrate 1400. That is, for example, fluorinated acid solution is prepared as polishing solution, and the glass substrate 1205 of the array substrate 1200 is polished by immersing the display cell 1000 in the polishing solution. Thereby, the surface of the array substrate 1200 dissolves and chemically changes to water glass. Since the surface of the array substrate 1200 is protected by the water glass at this time, the array substrate 1200 is swung to expose a new substrate face as needed, and to exfoliate the water glass.

Then, after the glass substrate is polished until the polishing stopper layer 1206 formed beforehand is exposed, the display cell 1000 is taken out from the fluorinated acid solution, and is washed by flowing water. Thereby, the surface water glass and the fluorinated acid solution are removed. Since all the cells are sealed by the temporary seal material 1106 at this time, the polishing solution does not enter into peripheral circuits of the cell when such chemical polish processing is performed.

Then, as shown in FIG. 6, the polishing stopper layer 1206 of the array substrate 1200 is removed. Here, the polishing stopper layer 1206 is removed from the array substrate 1200, in which whole glass substrate is polished away using an alkaline solution (for example, TMAH). Thereby, the ground insulating layer 1203 is exposed in the array substrate 1200.

Then, the large-sized display cell 1000 is divided into individual pixel cells leaving the effective display region and the peripheral circuit unit in each pixel cell. A scribing process is performed simultaneously for the array substrate 1200 equipped with the first pixel formation part 1220, etc., and the counter substrate 1400 of a non-glass material base using a cutting equipment, such as CO₂ laser type or the second to fourth harmonics YAG laser type.

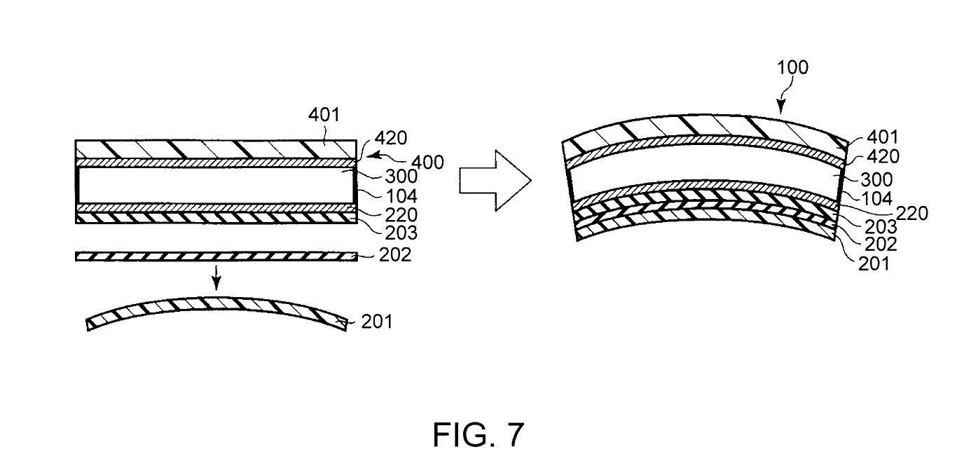

As shown in FIG. 7, each display cell (here, liquid crystal display panel 100) used as single piece includes a ground insulating layer 203 and a first pixel formation part 220 cut from the array substrate 1200, the second insulating substrate 401 and the second pixel formation part 420 cut from the counter substrate 1400, a liquid crystal layer 300 held between the first pixel formation part 220 and the second pixel formation part 420, and a seal material 104.

Then, after applying the adhesives 202 at least to one side of the exposed ground insulating layer 203 and the first insulating substrate 201 formed of non-glass material, the ground insulating layer 203 and the first insulating substrate 201 are attached with the adhesives 202. The first insulating substrate 201 is formed of the same quality material as the second insulating substrate 401. Moreover, in the example shown in FIG. 7, a substrate beforehand processed into nonplanar shape is applied as the first insulating substrate 201. That is, the first insulating substrate 201 applied here has an internal free energy which becomes the minimum, when it is in a nonplanar shape.

Then, the liquid crystal display device 1 having the nonplanar shape or a cylinder side face is manufactured by attaching optical elements, such as a polarizing plate to the liquid crystal display panel 100.

Thus, the first insulating substrate 201 is designed so that the internal free energy of the first insulating substrate 201 becomes the minimum, when the first insulating substrate 201 attached to the ground insulating layer 203 is in the state where the nonplanar shape is maintained. Therefore, it becomes possible to manufacture the display device which presents almost the same nonplanar shape as the first insulating substrate 201, which is memorized in the first insulating substrate 201, without applying external force to the display cell from the ground insulating layer 203 to the second insulating substrate 401.

Moreover, the corresponding components currently used in the flat display device can divert for most of components, such as the array substrate 200, the counter substrate 400, the color filter layer CF, and the liquid crystal material for forming the liquid crystal display panel 100. Accordingly, since the first insulating substrate 201 of the non-glass material is attached to the display cell beforehand assembled in the state of the plane shape, it becomes possible to easily provide the nonplanar display device without affecting the reliability and massive production efficiency of the liquid crystal display panel 100.

In addition, the embodiment is not restricted to the example in which the first insulating substrate 201 is beforehand processed into the nonplanar shape.

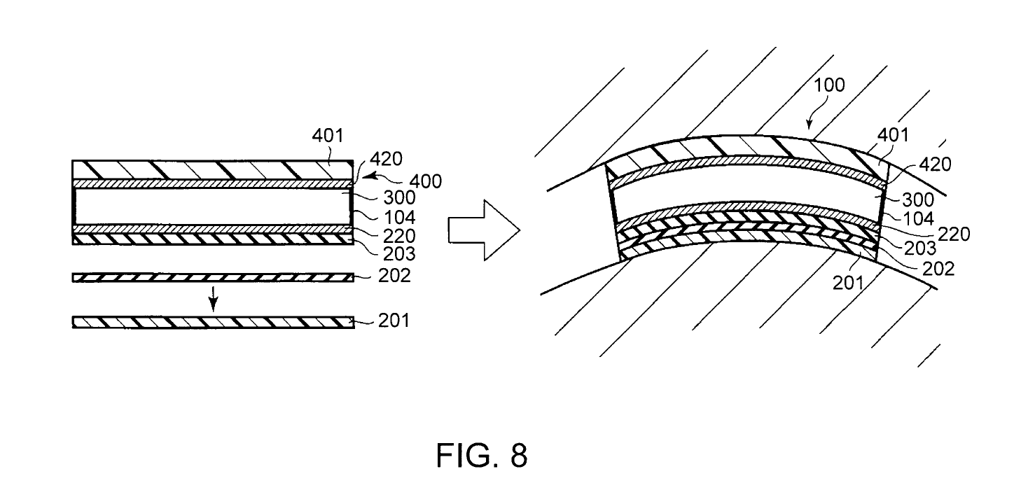

For example, as shown in FIG. 8, after applying the adhesives 202 to either the ground insulating layer 203 or the approximately plate-like first insulating substrate 201, the ground insulating layer 203 and the first insulating substrate 201 are attached so as to be fixed in a nonplanar shape in the state where the adhesives are in an uncured state. Then, the liquid crystal display device 1 of the nonplanar shape may be manufactured by curing the adhesives 202. When fixing, suitable external force is applied using a mold. In this example shown here, the adhesives 202 are designed in consideration of the balance between the energy to maintain a non-plane state and the energy forcing the plate-like first insulating substrate 201, etc., to return to the original form.

Thus, when attaching the plate-like first insulating substrate 201 and the display cell from the ground insulating layer 203 to the second insulating substrate 401, the adhesives 202 are cured in the state where the attached plate-like first insulating substrate 201 and the display cell are fixed in the nonplanar shape by applying external force. The hardened adhesives 202 in the nonplanar shape try to maintain this nonplanar shape. On the other hand, the plate-like first insulating substrate 201 and the display cell try to return from the curved state to the original plane shape. That is, the first insulating substrate 201 and the display cell are laminated through the adhesives 202 having the force of maintaining the nonplanar shape. Accordingly, it becomes possible to reduce own internal stress and to improve reliability compared with the nonplanar display device formed by changing the shape of a common flat display device by applying external force.

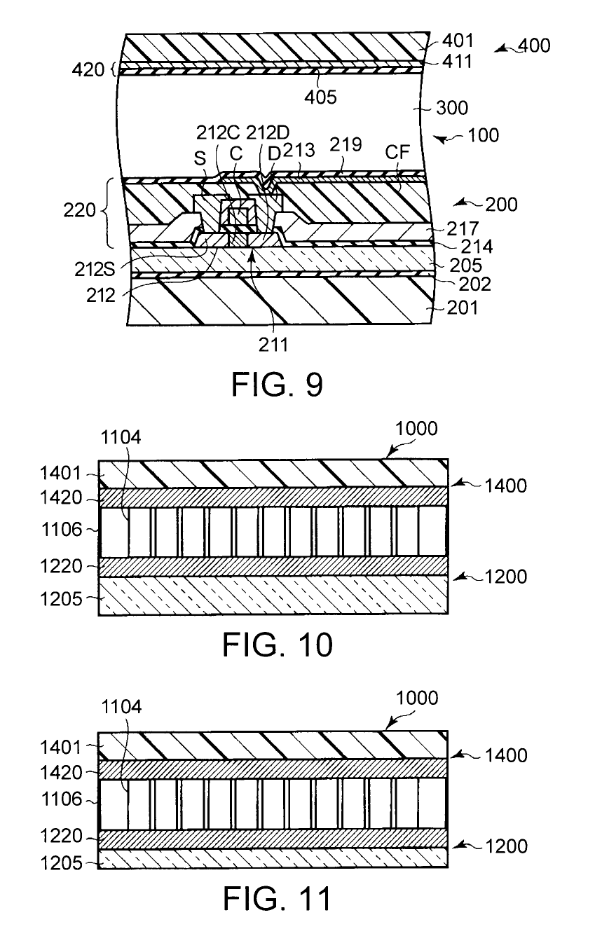

FIG. 9 is a cross-sectional view schematically showing the example of the second structure of the liquid crystal display panel 100 shown in FIG. 1.

This example of the second structure is different as compared with the example of the first structure in the point that the first insulating substrate 201 and the thin plate-like glass substrate 205 are attached through the adhesives 202 in the array substrate 200. Other structures are the same as those of the example of the first structure, and the same referential mark is attached and detailed explanation is omitted.

Thickness of the glass substrate 205 is set within the range of 0.15 mm to 0.1 mm. In the illustrated example, although the first pixel formation part 220, such as the switching element 211, are formed on the glass substrate 205, the ground insulating layer 203 explained in the example of the first structure may be arranged between the glass substrate 205 and the first pixel formation part 220.

Next, the manufacturing method of the liquid crystal display panel 100 of the example of the second structure shown in FIG. 9 is explained. Here, the manufacturing method of the multiple pattern cell which forms a plurality of liquid crystal display panels 100 from the large-sized display cell 1000 is explained as an example.

Firstly, the large-sized display cell 1000 is formed as shown in FIG. 10. Here, the first pixel formation part 1220 is formed on the glass substrate 1205 using a conventional TFT array manufacturing process, etc. Thereby, the large-sized array substrate 1200 is completed. The polishing stopper layer explained in the example of the first structure is not formed in this array substrate 1200. On the other hand, the second pixel formation part 1420 is formed on the second insulating substrate 1401 made of the non-glass material. Thereby, the large-sized counter substrate 1400 is manufactured.

Then, after applying a seal material 1104 and a temporary seal material 1106 arranged so that all effective display regions are surrounded along the outer edge of the array substrate 1200 and the counter substrate 1400, liquid crystal material is dropped in each effective display region, and the array substrate 1200 and the counter substrate 1400 are attached together with a predetermined cell gap. Thereby, the display cell 1000 enclosing the liquid crystal material in each effective display region is manufactured.

Then, as shown in FIG. 11, the glass substrate 1205 of the array substrate 1200 which constitutes the display cell 1000 is made thin. Here, the glass substrate 1205 of the array substrate 1200 is polished by performing chemical polish processing for the unified array substrate 1200 and the counter substrate 1400. That is, for example, fluorinated acid solution is prepared as polishing solution, and the glass substrate 1205 of the array substrate 1200 is polished by immersing the display cell 1000 in the polishing solution. Thereby, the surface of the array substrate 1200 dissolves and chemically changes to water glass. Since the surface of the array substrate 1200 is protected by the water glass at this time, the array substrate 1200 is swung to expose a new substrate face as needed, and to exfoliate the water glass.

Then, after the glass substrate is polished until the thickness of the glass substrate 1205 becomes in the range between 0.015 mm to 0.1 mm, for example, 0.05 mm, the display cell 1000 is taken out from the fluorinated acid solution, and is washed by flowing water. Thereby, the surface water glass and the fluorinated acid solution are removed. Since all the cells are sealed by the temporary seal material 1106 at this time, the polishing solution does not enter into peripheral circuits of the cell when such chemical polish processing is performed.

In this case, the process of removing the polishing stopper layer using an alkaline solution can be skipped because the polishing stopper layer becomes unnecessary.

Then, the display cell is divided into individual pixel cells leaving the effective display region and the peripheral circuit unit in the each pixel cell. A scribing process is performed simultaneously for the array substrate 1200 equipped with the first pixel formation part 1220, etc., and the counter substrate 1400 of a non-glass material base using a cutting equipment, such as CO₂ laser type and the second to fourth harmonics YAG laser type.

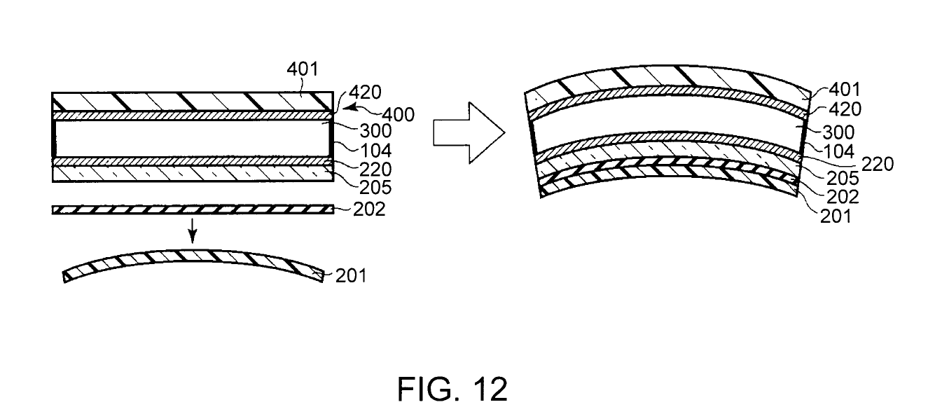

As shown in FIG. 12, each display cell (here, liquid crystal display panel 100) used as single piece includes a glass substrate 205 and a first pixel formation part 220 cut from the array substrate 1200, the second insulating substrate 401 and the second pixel formation part 420 cut from the counter substrate 1400, a liquid crystal layer 300 held between the first pixel formation part 220 and the second pixel formation part 420, and a seal material 104.

Then, after applying the adhesives 202 at least to one side of the thin plate-like glass substrate 205 and the first insulating substrate 201 formed of non-glass material, the glass substrate 205 and the first insulating substrate 201 are attached with the adhesives 202. The first insulating substrate 201 is formed of the same quality material as the second insulating substrate 401. Moreover, in the example shown in FIG. 12, a substrate beforehand processed into nonplanar shape is applied as the first insulating substrate 201. That is, the first insulating substrate 201 applied here has an internal free energy which becomes the minimum, when it is in a nonplanar shape.

Then, the liquid crystal display device 1 having the nonplanar shape or the cylinder side face is manufactured by attaching together optical elements, such as a polarizing plate, to the liquid crystal display panel 100.

In addition, the embodiment is not restricted to the example in which the first insulating substrate 201 is beforehand processed into the nonplanar shape.

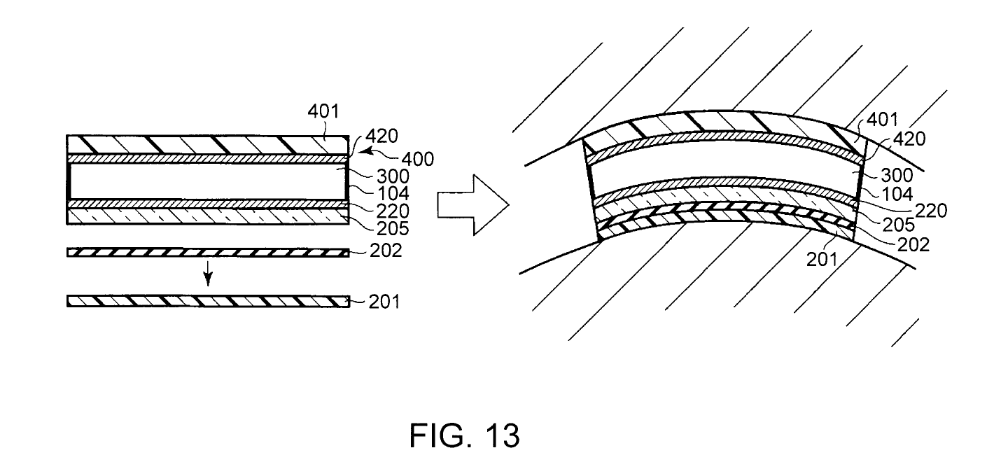

For example, as shown in FIG. 13, after applying the adhesives 202 to either the glass substrate 205 or the approximately plate-like first insulating substrate 201, the glass substrate 205 and the first insulating substrate 201 are attached so as to be fixed in a nonplanar shape in the state where the adhesives are an uncured state. Then, the liquid crystal display device 1 of the nonplanar shape may be manufactured by curing the adhesives 202.

When fixing, suitable external force is applied using a mold. In this example shown here, the adhesives 202 are designed in consideration of the balance between the energy to maintain a non-plane state and the energy forcing the plate-like first insulating substrate 201, etc., to return to the original form.

The same effect as the example of the first structure is acquired also in the example of the second structure.

In each example of the structure as mentioned-above, it is possible to suppress the increasing in the manufacturing cost when manufacturing the nonplanar display device.

That is, a problem of destroying the display cell, which is originated from the applied external force, is caused in the manufacturing process where after forming a plate-like display cell, the display cell is made flat by applying external force to whole display cell, responding to the demand for the nonplanar display device. Moreover, when using a substrate with nonplanar shape curved beforehand, and made by repeating the conventional film forming and patterning capable of maintaining the shape without applying the external force, there is industrial difficulty to handle the non-plane-shaped substrate to form the nonplanar display device. Accordingly, above process has a problem that the process is not suitable for massive production.

Then, the array substrate is formed using almost same process as that to manufacture the flat display device by film formation and patterning one by one on the plate-like glass substrate in the manufacturing process of a nonplanar display device according to this embodiment. In the manufacturing process of the counter substrate, almost the same process as that to manufacture the flat display is used except having changed the substrate into the insulating substrate formed of the non-glass material. Further, one drop filling method, which is employed to manufacture the flat display device, is used to form the liquid crystal layer between the array substrate and the counter substrate.

For this reason, a new manufacturing line exclusively used for a non-glass substrate is not necessary for the cell process. Further, the rising in the manufacturing cost due to starting of a new line or change of the process is suppressed while it becomes possible to inherit the reliability which is cultivated in the current cell process of manufacturing the flat display device.

Moreover, an insulating substrate of the non-glass material is attached after the process for removing the glass substrate on the array substrate side, or the process for making the glass substrate thinner. At this time, the array substrate is attached to the insulating substrate of the non-glass material beforehand processed into nonplanar shape. Otherwise, the array substrate is fixed in the nonplanar shape before the adhesives are cured. The nonplanar display device is manufactured by curing the adhesives finally.

For this reason, it is necessary to perform neither film forming nor patterning one by one on the substrate with nonplanar shape. Therefore, it becomes possible to reduce the difficulty in handling the non-plane-shaped substrate. Moreover, it becomes possible to reduce the manufacturing cost by reducing the use of indirect materials as much as possible, such as a protection layer at the time of removing at least a portion of the glass substrate. Further, it becomes possible to control the fall of the manufacturing yield.

In case the liquid crystal display panel 100 is used as the display cell, since it is necessary to remove at least a portion of the glass substrate of the array substrate in the state where the panel is filled up with the liquid crystal material beforehand, it is preferable to use a general one drop filing method in the assembly process. According to this method, self-bearing properties of the first pixel formation part 220 is improved comparing with the structure in which a space is provided between the first pixel formation part 220 of the array substrate and the second pixel formation part 420 of the counter substrate in the process of removing the glass substrate. Accordingly, it becomes easy to keep the distance (cell gap) between the first pixel formation part 220 and the second pixel formation part 420 uniform.

As the process of removing the glass substrate of the array substrate, it is possible to apply a mechanical polishing and a compound polishing consisting of the mecaninal polishing and the chemical polishing by turns besides the chemical polishing using the medical fluid as mentioned-above as a process of removing the glass substrate of the array substrate. In case the thickness of the first pixel formation part 220 is very thin (for example, a thickness of 1 μm-about 5 μm), following process is preferable. Firstly, the throughput of the polishing process is raised by rough polishing using the mechanical polishing, and then the glass is removed partially or completely by the chemical polishing as a process according to this embodiment.

When completely removing the glass substrate of the array substrate by the chemical etching, a polishing stopper layer formed of a fluorinated acid resistance thin film, such as an amorphous silicon thin film, is formed beforehand between the glass substrate and the first pixel formation part 220 so that the first pixel formation part 220 can bear the medical fluids (ammonium fluoride, etc.) used for the chemical polishing. In addition, when not removing completely the glass substrate of the array substrate, the polishing stopper layer is unnecessary (i.e., in case the glass is made thinner).

As components of the first pixel formation part 220, the components can be formed of aluminum (AL), silicon nitride (SiNx), ITO (Indium Tin Oxide), poly-silicon (p-Si), amorphous silicon (a-Si), copper (Cu), molybdenum (Mo), tantalum (Ta), tungsten (W), silicon oxide (SiOx), etc. That is, all the layers may be formed of inorganic films. However, when the self-bearing properties at the time of polishing of the glass substrate are taken into consideration, it is preferable to adopt an inorganic-organic hybrid thin film structure which contains the organic thin film with flexibility, such as acrylic resin, epoxy resin, and silicone resin, in a lamination structure in addition to the above-mentioned inorganic film.

Especially, as an example of the structure of inorganic-organic hybrid thin film, COA (Color filter On Array) structure including a color filter layer CF in the array substrate may be used. Further, a pixel electrode top arrangement structure, in which the pixel electrode 213 and the switching elements 211 are separated to enlarge the aperture ratio by arranging a transmissive resist layer therebetween, may be also used. Furthermore, it is preferable to adopt a structure of arranging an overcoat layer formed of the colored resist material or transparent resist material for forming above-mentioned color filter layer CF on the peripheral circuit in order to improve self-bearing properties of the switching element 211.

As explained above, according to this embodiment, the nonplanar display device and its manufacturing process can be offered, in which the increase in the manufacturing cost is suppressed.

In this embodiment as mentioned-above, the liquid crystal display device is explained as a nonplanar display device. However, the structure of the liquid crystal display panel 100 is not restricted to the above structure. For example, the counter electrode 411 may be formed on the array substrate 200 which is the same substrate as the pixel electrode 213. With respect to the liquid crystal mode, there is no restriction in particular. For example, the modes which mainly use vertical electric field, such as TN (Twisted Nematic) mode, OCB (Optically Compensated Bend) mode, VA (Vertical Aligned) mode may be used. Further, the modes which mainly use lateral electric field, such as IPS (In-Plane Switching) mode and FFS (Fringe Field Switching) mode, are also applicable.

Moreover, when the nonplanar display device is constituted by an organic electroluminescence display, the display cell is formed as follows. After forming an organic luminescence layer on the pixel electrode of the array substrate and forming a counter electrode on the organic luminescence layer, the array substrate and the counter substrate are attached together by a seal material and a temporary seal material. Thus, after forming the display cell, the same processes as those of the above-mentioned example of the first structure and the example of the second structure are used according to this embodiment.

While certain embodiments have been described, these embodiments have been presented by way of example only, and are not intended to limit the scope of the inventions. In practice, the structural and method elements can be modified without departing from the spirit of the invention. Various embodiments can be made by properly combining the structural and method elements disclosed in the embodiments. For example, some structural and method elements may be omitted from all the structural and method elements disclosed in the embodiments. Furthermore, the structural and method elements in different embodiments may properly be combined. The accompanying claims and their equivalents are intended to cover such forms or modifications as would fall with the scope and spirit of the inventions.

What is claimed is:

1. A method of manufacturing a nonplanar display device, the nonplanar display device including;
an array substrate having;
a glass substrate,
a polishing stopper layer formed on the glass substrate,
a ground layer formed on the polishing layer,
a switching element arranged on the ground layer, and
a pixel electrode connected to the switching element, and
a counter substrate formed of non-glass material;
the manufacturing method comprising the steps:
forming a display cell by attaching the array substrate and the counter substrate;
removing the glass substrate from the display cell;
removing the polishing stopper layer of the array substrate; and
manufacturing the nonplanar display device by attaching the exposed ground layer of the array substrate and an insulating layer formed of the non-glass material in the display cell.

2. The method of manufacturing a nonplanar display device according to claim 1, wherein the insulating substrate is formed in a nonplanar shape beforehand.

3. The method of manufacturing a nonplanar display device according to claim 1, wherein the nonplanar display device is formed in a cylinder side face shape.

4. The method of manufacturing a nonplanar display device according to claim 1, wherein the insulating substrate is formed approximately plate-like, and the insulating substrate is fixed so as to be the nonplanar shape in a state where adhesives are not cured, and then the adhesives are cured.

5. The method of manufacturing a nonplanar display device according to claim 1, wherein a liquid crystal material is dropped prior to attaching the array substrate and the counter substrate.

6. The method of manufacturing a nonplanar display device according to claim 1, further comprising the steps;
forming an organic electro-luminescence layer on the pixel electrode of the array substrate,
forming a counter substrate on the organic electro-luminescence layer, and
successively, attaching the array substrate and the counter substrate.

7. A method of manufacturing a nonplanar display device, the nonplanar display device including;
an array substrate having;
a glass substrate,
a switching element arranged on the glass substrate, and
a pixel electrode connected to the switching element,
a counter substrate formed of non-glass material; and
the manufacturing method comprising the steps:
forming a display cell by attaching the array substrate and the counter substrate;
making the glass substrate of the array substrate thinner; and
manufacturing the nonplanar display device by attaching the glass substrate of the array substrate and an insulating layer formed of the non-glass material.

8. The method of manufacturing a nonplanar display device according to claim 7, wherein the thickness of the glass substrate is set to a range of 0.15 mm to 0.1 mm when the glass substrate is made thinner.

9. The method of manufacturing a nonplanar display device according to claim 7, wherein the nonplanar display device is formed in a cylinder side face shape.

10. The method of manufacturing a nonplanar display device according to claim 7, wherein the insulating substrate is formed in a nonplanar shape beforehand.

11. The method of manufacturing a nonplanar display device according to claim 7, wherein the insulating substrate is formed approximately plate-like, and the insulating substrate is fixed so as to be the nonplanar shape in a state where adhesives are not cured, and then the adhesives are cured.

12. The method of manufacturing a nonplanar display device according to claim 7, wherein a liquid crystal material is dropped prior to attaching the array substrate and the counter substrate.

13. The method of manufacturing a nonplanar display device according to claim 7, further comprising the steps;
forming an organic electro-luminescence layer on the pixel electrode of the array substrate,
forming a counter substrate on the organic electro-luminescence layer, and
successively, attaching the array substrate and the counter substrate.

14. A nonplanar display device, comprising:
an array substrate including;
a nonplanar insulating substrate formed of non-glass material,
a ground layer attached to the insulating substrate,
a switching element arranged on the ground layer, and
a pixel electrode connected to the switching element, and
a counter substrate formed of non-glass material and attached to the array substrate.

15. A nonplanar display device according to claim 14, wherein the nonplanar display device is formed in a cylindrical side face shape.
